(19) United States
(12) Patent Application Publication
(10) Pub. No.: US 2015/0362533 A1
(43) Pub. Date: Dec. 17, 2015

(54) METHOD AND SYSTEM FOR MONITORING EQUIPMENT AT MEDIUM VOLTAGE

(71) Applicant: Solcon Industries Ltd., Yoqneam Illit (IL)

(72) Inventor: Gabbi ZENNOU, Haifa (IL)

(21) Appl. No.: 14/306,245

(22) Filed: Jun. 17, 2014

(51) Int. Cl. G01R 15/22; G01R 19/32; G01R 19/22

(52) U.S. Cl. CPC G01R 15/22; G01R 19/22; G01R 19/32

(57) ABSTRACT

A system for monitoring electrical equipment operative at a medium voltage that is isolated from a low voltage environment includes a transmitter unit that is operative at the medium voltage. The transmitter unit produces an optical signal that is indicative of at least one measured property of the electrical equipment. The optical signal is transmitted via an optical fiber to a low voltage receiver within the low voltage environment.

### FIELD OF THE INVENTION

The present invention relates to a system and method of monitoring of medium voltage equipment systems.

### BACKGROUND OF THE INVENTION

In a typical electric power transmission and distribution system, various segments of the system operate at different voltage levels. For example, the voltage of a long-distance electrical power transmission line may be sufficiently high so as to reduce transmission losses to an acceptable level. A power distribution system at a more local lever may operate at medium voltage (MV) levels, e.g., between 1 kV and 36 kV. Finally, end users, both residential and commercial, may receive electrical power at voltages sufficiently low to protect the safety of the users.

### SUMMARY OF THE INVENTION

There is thus provided, in accordance with some embodiments of the present invention, a system for monitoring electrical equipment operative at a medium voltage that is isolated from a low voltage environment, the system including a transmitter unit operative at the medium voltage to produce an optical signal that is indicative of at least one measured property of the electrical equipment, and to transmit the optical signal via an optical fiber to a low voltage receiver within the low voltage environment.

Furthermore, in accordance with some embodiments of the current invention, the transmitter unit includes a plurality of component units, each of the component units being configured to transmit an optical signal that is indicative of a property that is measured by that component unit.

Furthermore, in accordance with some embodiments of the current invention, each of the component units is directly connectable to a different bus bar of a system of bus bars, each of the bus bars carrying a different phase of a three phase electrical distribution system.

Furthermore, in accordance with some embodiments of the current invention, a component unit of the component units is connectable via another of the component units to the bus bar to which that other component unit is connected.

Furthermore, in accordance with some embodiments of the current invention, the property that is measured by that component unit includes a potential difference between the phase that is carried by the bus bar to which that component unit is directly connected, and the phase that is carried by the bus bar to which that component unit is connected via another of the component units.

Furthermore, in accordance with some embodiments of the current invention, a power supply of a component unit of the component units is configured to be powered by a potential difference between the phase that is carried by the bus bar to which that component unit is directly connected, and the phase that is carried by the bus bar to which that component unit is connected via another of the component units.

Furthermore, in accordance with some embodiments of the current invention, one component unit of the component units is configured to receive the optical signal that is transmitted by another component units of the component units, the optical signal that is transmitted by that one component unit being indicative of the property that is measured by the one component unit and of the property that is measured by the other component unit.

Furthermore, in accordance with some embodiments of the current invention, the measured property is selected from a group of properties consisting of potential difference, current, and temperature.

Furthermore, in accordance with some embodiments of the current invention, the transmitter unit includes a current transformer and the measured property includes a current.

Furthermore, in accordance with some embodiments of the current invention, the measured property includes a plurality of measured properties, and the optical signal is indicative of the plurality of measured properties.

Furthermore, in accordance with some embodiments of the current invention, the transmitter unit includes an analog-to-digital converter for converting an analog signal that is generated by a sensor that measures the property to a digital signal.

Furthermore, in accordance with some embodiments of the current invention, the system includes a processing unit for generating an encoded signal for producing the optical signal based on an input electronic signal that is indicative of the measured property.

Furthermore, in accordance with some embodiments of the current invention, the encoded signal is Manchester encoded.

Furthermore, in accordance with some embodiments of the current invention, the processing unit includes a complex programmable logic device.

Furthermore, in accordance with some embodiments of the current invention, an optical fiber that is connectable to the transmitter unit and to the low voltage receiver.

There is further provided, in accordance with some embodiments of the present invention, a method for monitoring electrical equipment that is operative at a medium voltage that is isolated from a low voltage environment, the method including: connecting a transmitter unit that is operative at the medium voltage to the equipment; connecting an optical fiber to the transmitter unit and to a low voltage receiver that is operative at a low voltage within the low voltage environment; and operating the transmitter unit to measure at least one measured property of the equipment and to produce an optical signal that is indicative of the at least one measured property.

Furthermore, in accordance with some embodiments of the current invention, connecting the transmitter unit includes directly connecting each component unit of a plurality of component units, each of the component units being configured to transmit an optical signal that is indicative of a property that is measured by that component unit, to a different bus bar of a system of bus bars, each of the bus bars carrying a different phase of a three phase electrical distribution system.

Furthermore, in accordance with some embodiments of the current invention, connecting the transmitter unit further includes connecting each of the component units via another of the component units to the bus bar to which that other component unit is connected.

Furthermore, in accordance with some embodiments of the current invention, the method further includes operating the low voltage receiver to produce an output that is indicative of the measured property.

There is further provided, in accordance with some embodiments of the present invention, a system for monitoring electrical equipment operative at a medium voltage that is isolated from a low voltage environment, the system including: a transmitter unit operative at medium voltage to produce an optical signal that is indicative of at least one measured property of the electrical equipment; an optical fiber that is connectable to the transmitter unit and that extends to the low voltage environment; and a low voltage receiver that is connectable to the optical fiber in the low voltage environment, and that is operable to receive the optical signal via the optical fiber and to produce an output that is indicative of the at least one measured property.

### BRIEF DESCRIPTION OF THE DRAWINGS

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1 is a schematic drawing of a medium voltage monitoring system, in accordance with an embodiment of the present invention.

FIG. 2 is a schematic drawing of a medium voltage transmitter unit of the medium voltage monitoring system shown in FIG. 1.

FIG. 3 is a block diagram that schematically illustrates components of the medium voltage transmitter unit shown in FIG. 2.

FIG. 4A is a schematic drawing of a low voltage receiver unit, in accordance with an embodiment of the present invention.

FIG. 4B is a block diagram that schematically illustrates components of the low voltage receiver unit shown in FIG. 4A.

FIG. 5 is a flowchart depicting a method for monitoring medium voltage equipment, in accordance with an embodiment of the present invention.

### DETAILED DESCRIPTION OF THE INVENTION

In the following detailed description, numerous specific details are set forth in order to provide a thorough understanding of the invention. However, it will be understood by those of ordinary skill in the art that the invention may be practiced without these specific details. In other instances, well-known methods, procedures, components, modules, units and/or circuits have not been described in detail so as not to obscure the invention.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium (e.g., a memory) that may store instructions to perform operations and/or processes. Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. Unless explicitly stated, the method embodiments described herein are not constrained to a particular order or sequence. Additionally, some of the described method embodiments or elements thereof can occur or be performed simultaneously, at the same point in time, or concurrently.

Some embodiments of the invention may include an article such as a computer or processor readable medium, or a computer or processor non-transitory storage medium, such as for example a memory, a disk drive, or a USB flash memory, encoding, including or storing instructions, e.g., computer-executable instructions, which when executed by a processor or controller, carry out methods disclosed herein.

In accordance with an embodiment of the present invention, a system is configured to monitor a medium voltage electrical system or equipment that is operative within a medium voltage compartment. The medium voltage compartment is enclosed or otherwise electrically isolated from a surrounding lower voltage environment. The medium voltage compartment is configured to isolate equipment, power lines, or devices that operate at a medium voltage from the surroundings. As used herein, any such device, power line, or other component that operates at the medium voltage and is to be monitored is herein referred to as medium voltage equipment.

Typically, medium voltage refers to alternating current voltages in the range of about 1 kV to about 36 kV. Devices and techniques referred to herein may also be applicable when the enclosed voltage is greater than or lower than this range. As used herein, medium voltage should be understood as referring to any compartment, enclosure, or environment that operates at a higher voltage than a surrounding lower voltage environment from which the higher voltage is electrically isolated.

A medium voltage monitoring system, in accordance with an embodiment of the present invention, includes one or more medium voltage transmitter units that are connected by an electrically insulating optical cable to a low voltage receiving unit that is located outside of the medium voltage compartment.

Each medium voltage transmitter unit includes one or more measurement devices and an optical transmitter. The medium voltage transmitter unit is powered by medium voltage power present within the medium voltage compartment. For example, the medium voltage transmitter unit may be connected to a medium voltage bus bar.

A measurement device, such as a voltmeter, a current meter, a thermometer, or other sensing or measuring device, is configured to measure or sense a property (e.g., voltage, current, power, temperature, or other property) within the medium voltage compartment. The measured property may be directly related to distributed electrical power or operation of equipment, or may be related to environmental conditions within the medium voltage compartment. For example, the measurement device may be directly connected to or mounted on a bus bar of the medium voltage compartment. The measurement device may be is configured to produce an electrical output signal that is indicative of the measured property.

An optical transmitter includes a converter that converts the electrical signal into an optical signal. For example, if the output signal from the measurement device is an analog signal, the analog signal may be digitized to a digital electronic signal by an analog-to-digital (A2D) converter. Multiple electrical signals (from analog or from digital output signals) may be multiplexed into a single digital electronic signal. For example, multiple output signals may be produced by different sensors or measuring devices.

The digital signal may than be converted to an optical signal that encodes the contents of the digital signal. For example, a complex programmable logic device (CPLD) or other processor may be programmed or configured to convert a digital electronic signal into an optical signal. Manchester coding or another encoding or protocol suitable for optical transmission may be utilized to encode the information carried by the digital electronic signal into an optical signal.

Two or more optical outputs may be multiplexed into a single optical output prior to transmission. For example, each of the optical outputs prior to multiplexing may be associated with a different phase of electrical power that is being distributed by the medium voltage system.

An electrically insulating optical transmission cable connects the optical transmitter to a receiver that is located outside of the medium voltage compartment. The optical cable may include one or more optical fibers. The optical cable or each optical fiber may be connected to an optical output port of the optical transmitter. For example, the optical cable may be constructed without any metallic or other conducting cladding or components.

The optical cable may pass through an opening in the enclosure of the medium voltage from inside the medium voltage compartment to outside the compartment. The opening may include or be surrounded by insulation (e.g., an insulating ring). The insulation may prevent any possibility of electric conduction between the medium voltage compartment and the surroundings.

A low voltage receiver unit may be connected to the end of the optical cable that is outside of the medium voltage compartment. The low voltage receiver unit includes an optical receiver that is configured to receive the optical signals. The low voltage receiver unit may also include one or more displays or other output devices to enable a user to review or examine data that is received via the optical receiver.

The outside end of the optical cable may connect to an optical input port of the optical receiver. The optical receiver is configured to convert the optical signal (e.g., Manchester encoded) into digital electronic signals. The optical receiver may be further configured to separate a multiplexed signal into its various components. For example, components of a signal may represent measurements related to different phases (e.g., of a three-phase voltage system), and different measurements (e.g., voltage, current, temperature, or other measurements) related to each phase.

The low voltage receiver unit, or a device in communication with the low voltage receiver unit, may enable communicating the received information for examination by a user. For example, the low voltage receiver unit may include a capability (e.g., a display) to display the received information. The low voltage receiver unit may include a processor that is configured to process the received data. For example, the processing may convert a representation of a raw measurement into a form (e.g., calibrated or otherwise processed) that may be understood by a human user.

As another example, the optical receiver may convert the received optical signal to an appropriate electronic signal. The electric signal may be communicated with one or more other devices incorporated into, or in communication with, the low voltage receiver unit. Each such device may be configured to process, analyze, display or otherwise handle or manipulate the received data and present the data to a user. For example, a device may include a computer or workstation. A user of the system may include an operator or supervisor of the medium voltage equipment, of an electrical distribution system, or other operator, supervisor, or user. The optical receiver and additional devices may be incorporated into a single low voltage receiver unit device, or may include two or more intercommunicating separated devices.

In some cases, for example, a medium voltage transmitter unit may be configured to digitize an analog signal of up to 24 MV with 16 bit resolution. Other analog ranges and digital resolutions are possible. The low voltage receiver unit may be configured to replicate the analog range with high level of accuracy. For example, a replicated low voltage analog signal may include three phases with an alternating current voltage of about 120 V.

A medium voltage monitoring system, in accordance with an embodiment of the present invention, may be advantageous. The medium voltage monitoring system may enable accurate, reliable, frequent (e.g., with a high sampling rate), and real time monitoring or measurement of currents, voltages, or other characteristics of equipment in a medium voltage compartment. The medium voltage monitoring system may be relatively compact, lightweight (e.g., no more than 3 kg), and inexpensive. Conversion or the measurements to a digital signal may enable simple storage of measured data and characteristics, as well as transmission of the data to a remote location over a network or otherwise. Storage of the data may enable examination of trends over time, e.g., by enabling graphic display of measurements as a function of time. Transmission of the data to a remote location may enable remote monitoring or diagnosis, and possibly remote maintenance, of the medium voltage equipment or system.

A medium voltage monitoring system, in accordance with an embodiment of the present invention, may be adaptable to a wide range of voltages (e.g., including the entire conventional medium voltage range of 1 kV to 36 kV, or a greater range).

Use of a medium voltage monitoring system in accordance with an embodiment of the present invention may be advantageous over other techniques. For example, another technique may include use of a medium voltage transformer (primary and secondary copper windings on a steel core) to reduce the voltage to a voltage level that could be measured with a standard voltmeter. Such a technique could require use of heavy (e.g., 5 kg to 50 kg) and large (e.g., about ten times larger than a medium voltage monitoring system in accordance with some embodiments of the present invention) transformers, possibly requiring a separate complete medium voltage compartment for the transformer. With such a transformer, there could be a risk of a short circuit, leakage, or accidental contact between the primary and secondary. Use of expensive high voltage protection fuses could be required. Such a technique could only be used to measure voltage. Current could be measured using a current transformer, but the measured signal would be transferred out of the medium voltage compartment using an additional set of conductors. Such a monitoring system could not be configured to transmit data that is not directly related to the current or voltage, such as temperature. Furthermore, a configuration of such a transformer could be limited to specific operating voltage. On the other hand an electronic device, in accordance with an embodiment of the present invention, may be adjusted to every voltage level with a simple field alignment.

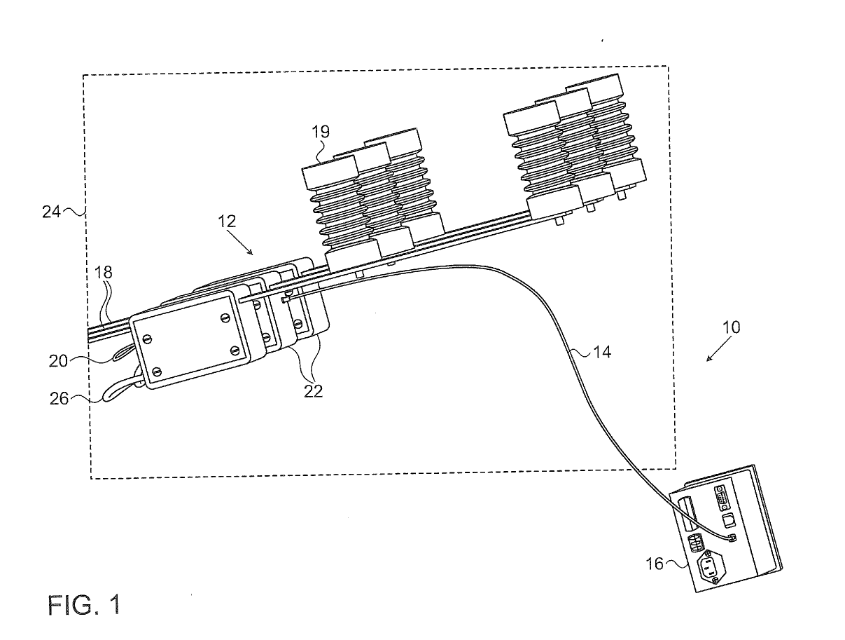

FIG. 1 is a schematic drawing of a medium voltage monitoring system, in accordance with an embodiment of the present invention.

Medium voltage monitoring system 10 includes a medium voltage transmitter unit 12 that is placed, when in use, within medium voltage compartment 24. Medium voltage compartment 24 is configured to electrically isolate an environment and equipment within medium voltage compartment 24 from an environment and equipment that are outside of medium voltage compartment 24.

Medium voltage transmitter unit 12 is configured to sense or measure one or more properties of a medium voltage system, power line, or equipment within that is operative at a medium voltage within medium voltage compartment 24. Electrical signals that encode or represent the measured properties are converted to an optical signal.

Medium voltage transmitter unit 12 may include one or more interconnected component transmitter units 22. In some cases, each component transmitter unit 22 may be connected to a different medium voltage bus bar 18. For example, each medium voltage bus bar 18, e.g., each mounted on one or more insulating posts 19, may carry one phase of a three phase power distribution system. In other cases, a medium voltage transmitter unit 12 may include more or less than three component transmitter units 22.

Although component transmitter units 22 are shown as rectangular boxes, a housing for each component transmitter unit 22 may be cast, molded, machined, or otherwise shaped to conform to a wide variety of required shapes. Several component transmitter units 22 may be encloses in a single housing.

Electrical interconnections 26 connect each component transmitter unit 22 to a medium voltage bus bar 18 to which another of component transmitter units 22 is connected. Electrical interconnections 26 may thus create within each component transmitter unit 22 a potential difference. The potential differences may be measured, and may be used to power components of each component transmitter unit 22.

Fiber optic interconnections 20 may enable communication between each component transmitter unit 22 and low voltage receiver unit 16 via a single optical cable 14. Optical cable 14 is electrically insulating (dielectric) and passes from within medium voltage compartment 24 to a low voltage environment outside of medium voltage compartment 24. Optical cable 14 is connectable to medium voltage transmitter unit 12 and to low voltage receiver unit 16. Thus, optical cable 14 may enable communication of an optical signal from medium voltage transmitter unit 12 to low voltage receiver unit 16.

Low voltage receiver unit 16 is located in the low voltage environment outside of medium voltage compartment 24. Low voltage receiver unit 16 is configured to connect to optical cable 14 and to receive an optical signal that is transmitted by medium voltage transmitter unit 12 via optical cable 14. Low voltage receiver unit 16 may be further configured to process or analyzed a received optical signal. Low voltage receiver unit 16 may include one or more output devices for communicating data that is extracted from a received optical signal to a user.

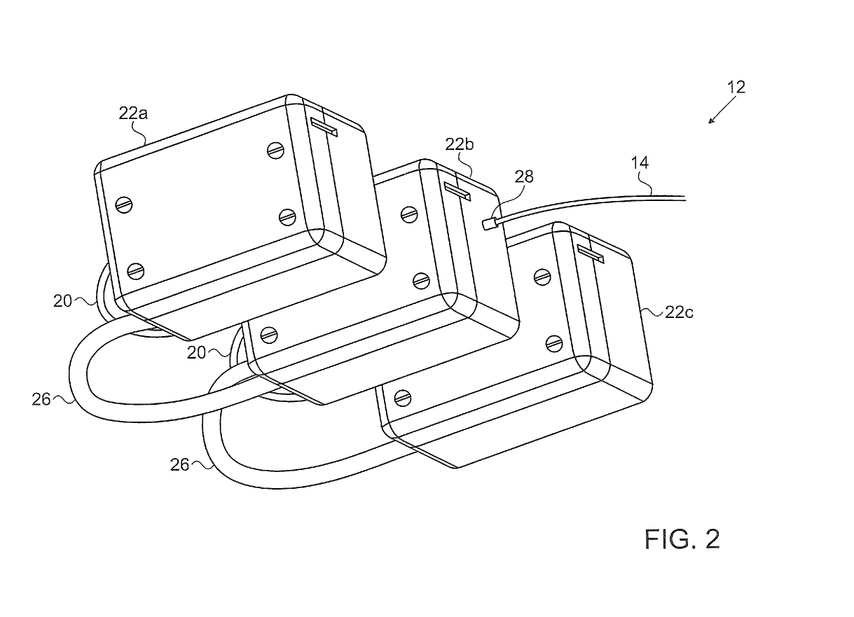

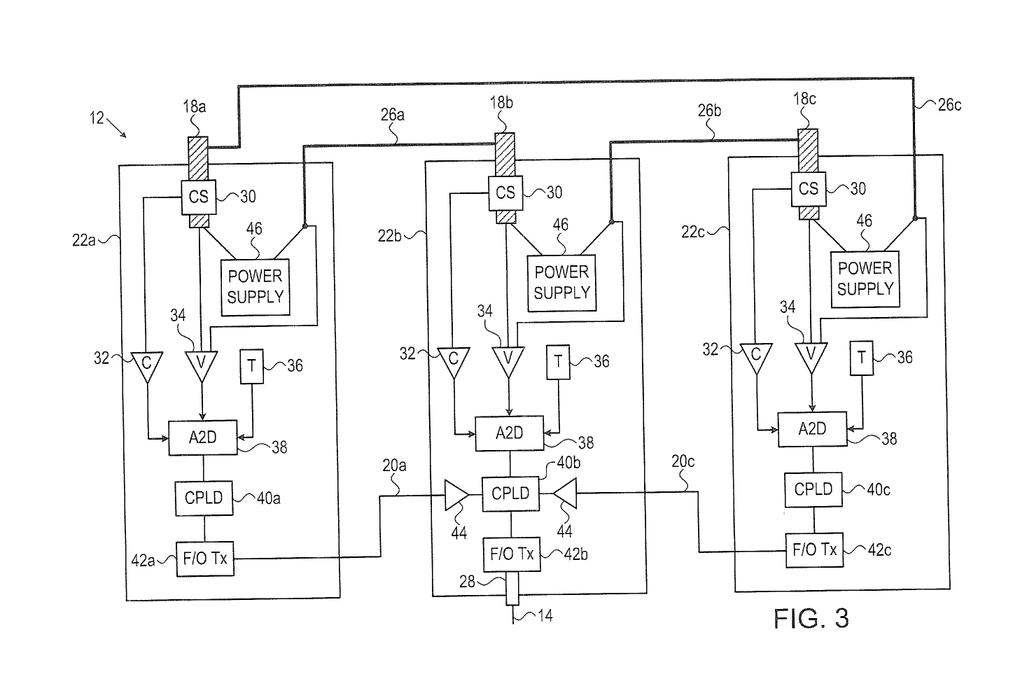

FIG. 2 is a schematic drawing of a medium voltage transmitter unit of the medium voltage monitoring system shown in FIG. 1. FIG. 3 is a block diagram that schematically illustrates components of the medium voltage transmitter unit shown in FIG. 2.

Medium voltage transmitter unit 12 includes three component transmitter units 22a-22c. Component transmitter units 22a-22c are each directly connected to one of medium voltage bus bars 18a-18c, respectively. Component transmitter units 22a-22c are not related to any common ground and are floating.

Each of component transmitter units 22a-22c may include a current sensor (CS) 30. Current sensor 30 may include a current transformer, Hall effect meter, shunt current meter, or another type of current sensing device. Each current sensor 30 is configured to generate a reduced current or low voltage signal whose current is lower than the current that is carried by the corresponding medium voltage bus bar 18a-18c. The reduced current is proportional to the current that is carried by the corresponding medium voltage bus bar 18a-18c. The reduced current level is measurable by a current meter or sensor, e.g., current amplifier 32 or another type of current meter or sensor. (In some cases, the functionality of current sensor 30 and current amplifier 32 may be incorporated into a single current sensor or meter.) Current amplifier 32 is configured to generate a voltage or analog voltage signal that is indicative of (e.g., proportional to) the reduced current level, and thus, of the current that is carried by the corresponding medium voltage bus bar 18a-18c.

Each of component transmitter units 22a-22c is also connected to a second bus bar of medium voltage bus bars 18a-18c via another of component transmitter units 22a-22c by one of electrical interconnections 26. Each electrical interconnection 26 includes a copper or other current conducting wire. For example, as shown, component transmitter unit 22a is connected to medium voltage bus bar 18b by electrical interconnection 26a. Similarly, component transmitter unit 22b is connected to medium voltage bus bar 18c by electrical interconnection 26b and component transmitter unit 22c is connected to medium voltage bus bar 18a by electrical interconnection 26c. In other examples, component transmitter units 22a-22c and medium voltage bus bars 18a-18c may be otherwise interconnected. In each component transmitter unit 22a-22c, one of the connected medium voltage bus bars 18a-18c may be considered to function as a local ground.

Voltage amplifier 34 (or another voltage meter or sensor) of each component transmitter unit 22a-22c is configured to generate a voltage or analog voltage signal that is indicative of (e.g., proportional to) a sensed potential difference. The sensed potential difference is between the two medium voltage bus bars 18a-18e to which each component transmitter unit 22a-22c is connected (one directly and the other via its corresponding electrical connection 26a-26c). For example, in component transmitter unit 22a, voltage amplifier 34 measures a potential difference between medium voltage bus bar 18a and medium voltage bus bar 18b. In component transmitter unit 22b, voltage amplifier 34 measures a potential difference between medium voltage bus bar 18b and medium voltage bus bar 18c. In component transmitter unit 22c, voltage amplifier 34 measures a potential difference between medium voltage bus bar 18c and medium voltage bus bar 18a. In other examples, other potential differences may be measured.

Power supply 46 of each component transmitter unit 22a-22c is powered by the potential difference between the two medium voltage bus bars 18a-18e to which that component transmitter unit 22a-22c is connected. For example, in component transmitter unit 22a, power supply 46 is powered by the potential difference between medium voltage bus bar 18a and medium voltage bus bar 18b. In component transmitter unit 22b, power supply 46 is powered by the potential difference between medium voltage bus bar 18b and medium voltage bus bar 18c. In component transmitter unit 22c, power supply 46 is powered by the potential difference between medium voltage bus bar 18c and medium voltage bus bar 18a. In other examples, other potential differences may be used to power a power supply 46.

Power supply 46 may provide electrical power to enable operation of one or more other components of each component transmitter unit 22a-22c. For example, power supply 46 may provide power for operation of one or more of current amplifier 32, voltage amplifier 34, temperature sensor 36, analog-to-digital converter 38e, processing unit 40a-40c, fiber optic transmitter 42a-42c, or another component of a component transmitter unit 22a-22c.

Each component transmitter unit 22a-22c may include one or more additional meters or sensors. Each such sensor may be configured to generate a voltage or an analog voltage signal that is indicative of a measured or sensed quantity.

For example, each component transmitter unit 22a-22c may include one or more temperature sensors 36. Each temperature sensor 26 may be configured to sense a local temperature and to generate a signal that is indicative of the sensed temperature. For example, each temperature sensor 26 may include a thermometer and circuitry for converting the sensed temperature to an output signal. A temperature sensor may measure a temperature of a medium voltage bus bar 18a-18c, of an interior point within a medium voltage compartment or within a component transmitter unit 22a-22c, an ambient temperature, or another relevant temperature.

Other sensors may be included. For example, a sensor may be configured to sense one or more environmental conditions, or another quantity of interest.

An analog signal that is generated by a current sensor such as current amplifier 32, by a voltage sensor such as voltage amplifier 34, by temperature sensor 36, or by another type of sensor, may be converted to a digital signal. Analog-to-digital (A2D) converter 38 is configured to convert an input analog voltage signal into a digital output signal. For example, analog-to-digital converter 38 may be configured to convert an analog signal to a digital signal with 16-bit resolution. The analog to digital conversion may have another conversion resolution.

Analog-to-digital converter 38 includes one or more analog-to-digital converters. Although a single analog-to-digital converter 38 is shown, separate analog-to-digital converters may be provided for each signal source or sensor. Such an arrangement may enable concurrent measurement of two or more quantities by different sensors. In some cases, an analog-to-digital converter may be incorporated into a sensor. In such a case, the sensor may directly output a digital signal that is indicative of a sensed quantity.

The digital signals that are output by analog-to-digital converter 38 may be converted to an optical signal format by an appropriate processing unit 40a-40c of each of component transmitter units 22a-22c, respectively. For example, each processing unit 40a-40c may include a complex programmable logic device (CPLD) or another type of programmable processing unit. Processing unit 40a-40c may be programmed to drive a corresponding fiber optic transmitter (F/O Tx) 42a-42c to generate an optical signal that encodes the digital output from analog-to-digital converter 38. For example, processing unit 40a-40c may be programmed to generate a serial Manchester encoded signal or otherwise encoded signal. The fiber optic transmitter 42a-42c may operate in accordance with the encoded signal to generate an optical signal that represents the sensed data. Each processing unit 40a-40c may be programmed to multiplex two or more digital input signals into a single output encoded signal.

Each fiber optic transmitter 42a-42c includes a light generating component. For example, the light generating component may include an appropriate light emitting diode, diode laser, or another appropriate type of light generating component. Each fiber optic transmitter 42a-42c may include circuitry that enables control or modulation of the light generating component, optics, or other components such as to generate a signal that faithfully reproduces the encoded signal. Each fiber optic transmitter 42a-42c may include components that enable or facilitate operation of fiber optic transmitter 42a-42c (e.g., collimators, lenses, apertures, or other components).

An optical signal that is generated by each fiber optic transmitter 42a and 42c is transmitted into a corresponding optical fiber 20a or 20c.

In some cases, each optical fiber 20a and 20c may extend out of a medium voltage compartment that encloses medium voltage transmitter unit 12 to a low voltage environment. In order to reduce the number of optical cables that penetrate the boundary between the medium voltage compartment and the low voltage environment, optical signals that encode sensor measurements from component transmitter units 22a-22c may be transmitted out of the medium voltage compartment via a single optical signal.

As shown, two component transmitter units, component transmitter units 22a and 22c, transmit generated optical signals via optical fibers 20a and 20c, respectively, to component transmitter unit 22b. Component transmitter unit 22b includes fiber optic receivers 44. Each fiber optic receiver 44 is configured to convert a received optical signal into a digital electronic signal. Transmission of a signal in the form of an optical signal from component transmitter units 22a and 22c to component transmitter unit 22b may prevent interference from the large currents that are present within the medium voltage compartment. In addition, transmission of an optical signal may enable proper operation of component transmitter units 22a-22c in the absence of a common electrical ground for any pair of component transmitter units 22a-22c.

Optical signals that are transmitted from component transmitter units 22a and 22c to component transmitter unit 22b are converted to digital electronic signals by fiber optic receivers 44. The converted electronic signals are input into processing unit 40b together with digital signals that are output from analog-to-digital converter 38 of component transmitter unit 22b. Processing unit 40b may then multiplex the input digital electronic signals to generate a single output encoded signal. The single output encoded signal may be used to operate fiber optic transmitter 42b to generate a single multiplexed optical signal in optical connector 28.

Other connection schemes may be used. For example, the component transmitter unit that transmits the optical signal to optical cable 14 may not be in the center.

A proximal end of optical cable 14 may be connected to optical connector 28. The distal end of optical cable 14 may be connected to an optical port of a low voltage receiver unit.

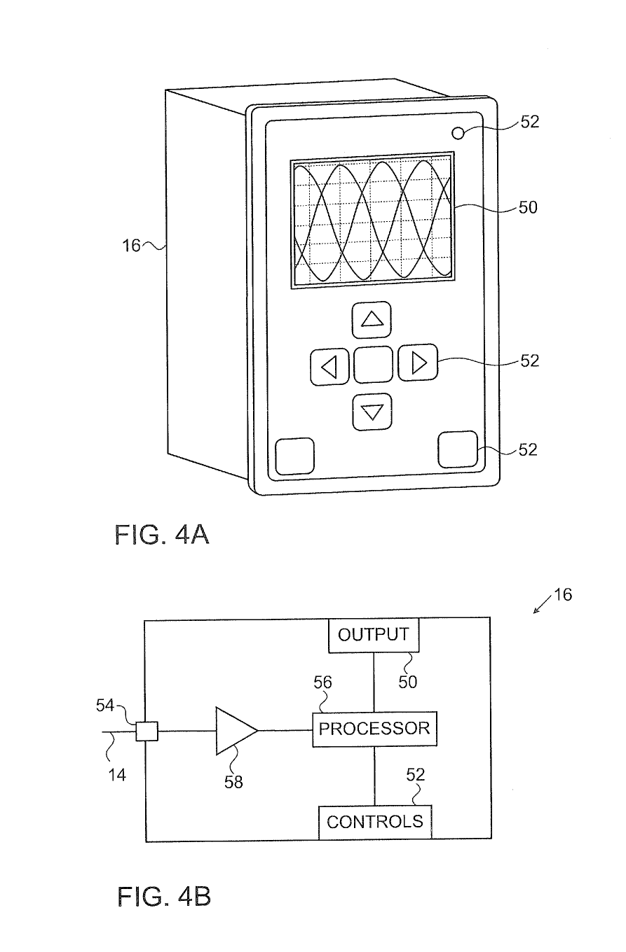

FIG. 4A is a schematic drawing of a low voltage receiver unit, in accordance with an embodiment of the present invention. FIG. 4B is a block diagram that schematically illustrates components of the low voltage receiver unit shown in FIG. 4A.

The distal end of optical cable 14 connects to optical receiver port 54 of low voltage receiver unit 16. An optical signal carried by optical cable 14 is transmitted to fiber optic receiver 58. Fiber optic receiver 58 converts the received optical signal into a digital or analog electronic signal. The electronic signal may be input into processor 56. Processor 56 may include one or more processing units that are configured to operate in accordance with programmed instructions. Processor 56 may include, incorporate, or communicate with one or more volatile or nonvolatile memory or data storage devices. Processor 56 may include, incorporate, or communicate with a clock or timer. Alternatively or in addition, processor 56 may include circuitry or one or more electronic circuits that are configured to perform one or more operations or manipulations on the electronic signal.

Processor 56 may be configured to interpret, analyze, or otherwise process an electronic signal or data that is encoded in the electronic signal. Processor 56 may be configured to calculate a quantity that is derived from the data (e.g., a power from data related to current and voltage, efficiency, a resistance or impedance, or another quantity derived from measured or sensed data). Processor 56 may be configured to store one or more measured or derived quantities or other information on a memory or data storage device, and to retrieve any stored data.

Processor 56 may be configured to operate one or more output devices 50. For example, an output device 50 may include one or more of a display screen, an alphanumerical display, an indicator light, a dial, a speaker or other sound-generating device, or another type of output device. For example, processor 56 may be configured to operate an output device 50 to show or indicate a sensed or measured quantity, such as a voltage, current, temperature, or other sensed or measured quantity. Processor 56 may be configured to operate an output device 50 to indicate whether one or more measured quantities are within or deviate from a predetermined range of values. Processor 56 may be configured to display a series of sequentially measured quantities, e.g., in the form of a waveform (e.g., in the manner of an oscilloscope), graph, or table. Operation of output device 50 may produce an output that may be monitored by a user in the low voltage environment.

Processor 56 may be configured to operate in a manner determined by operation of one or more user controls 52. A user control 52 may include a pushbutton, touch screen, switch, knob, lever, or other type of user operable control. For example, operation of a user control 52 may indicate which data is to be displayed, a scale of the displayed data, a selected portion of the data to be displayed (e.g., of a displayed segment of a graphic display of a measured quantity over time), or another manner of displaying data.

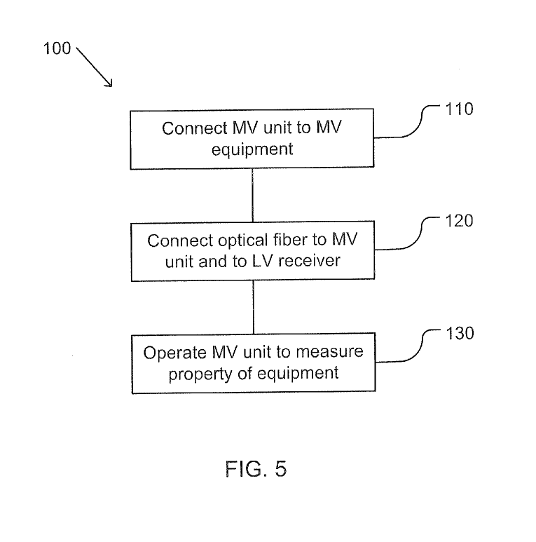

FIG. 5 is a flowchart depicting a method for monitoring medium voltage equipment, in accordance with an embodiment of the present invention.

Monitoring method 100 includes connecting a medium voltage (MV) transmitter unit to equipment that is designed to operate at a medium voltage that is isolated from a low voltage (LV) environment (block 110). For example, each component unit of the medium voltage transmitter unit may be directly connected to a different bus bar of a system of bus bars, e.g., each carrying a different phase of a three phase electrical distribution system. Each of the component units may be connected via another of the component units to the bus bar to which the other component unit is connected.

An optical cable, including one or more optical fibers, is connected to the transmitter unit and to a low voltage receiver unit within the low voltage environment (block 120). Thus, the optical cable crosses a barrier or boundary between the medium voltage environment (e.g., enclosed within a medium voltage compartment) and the low voltage environment.

The transmitter unit is operated to measure at least one measured property of the medium voltage equipment (block 130). An optical signal is produced that is encodes, or is otherwise indicative of, the measured property. The low voltage receiver may receive the optical signal. An output device of the low voltage receiver may be operated to produce output that is indicative the measured property of the medium voltage equipment. Thus, one or more properties of the medium voltage equipment may be monitored by a user who is located within the low voltage environment.

1. A system for monitoring electrical equipment operative at a medium voltage that is isolated from a low voltage environment, the system comprising a transmitter unit operative at the medium voltage to produce an optical signal that is indicative of at least one measured property of the electrical equipment, and to transmit the optical signal via an optical fiber to a low voltage receiver within the low voltage environment.

2. The system of claim 1, wherein the transmitter unit comprises a plurality of component units, each of the component units being configured to transmit an optical signal that is indicative of a property that is measured by that component unit.

3. The system of claim 2, wherein each of the component units is directly connectable to a different bus bar of a system of bus bars, each of the bus bars carrying a different phase of a three phase electrical distribution system.

4. The system of claim 3, wherein a component unit of the component units is connectable via another of the component units to the bus bar to which that other component unit is connected.

5. The system of claim 4, wherein said property that is measured by that component unit comprises a potential difference between the phase that is carried by the bus bar to which that component unit is directly connected, and the phase that is carried by the bus bar to which that component unit is connected via another of the component units.

6. The system of claim 4, wherein a power supply of a component unit of the component units is configured to be powered by a potential difference between the phase that is carried by the bus bar to which that component unit is directly connected, and the phase that is carried by the bus bar to which that component unit is connected via another of the component units.

7. The system of claim 2, wherein one component unit of the component units is configured to receive the optical signal that is transmitted by another component units of the component units, the optical signal that is transmitted by that one component unit being indicative of the property that is measured by the one component unit and of the property that is measured by the other component unit.

8. The system of claim 1, wherein said at least one measured property is selected from a group of properties consisting of potential difference, current, and temperature.

9. The system of claim 1, wherein the transmitter unit comprises a current transformer and said at least one measured property comprises a current.

10. The system of claim 1, wherein said at least one measured property comprises a plurality of measured properties, and the optical signal is indicative of said plurality of measured properties.

11. The system of claim 1, wherein the transmitter unit comprises an analog-to-digital converter for converting an analog signal that is generated by a sensor that measures the property to a digital signal.

12. The system of claim 1, comprising a processing unit for generating an encoded signal for producing the optical signal based on an input electronic signal that is indicative of the measured property.

13. The system of claim 12, wherein the encoded signal is Manchester encoded.

14. The system of claim 12, wherein the processing unit comprises a complex programmable logic device.

15. The system of claim 1, further comprising an optical fiber that is connectable to the transmitter unit and to the low voltage receiver.

16. A method for monitoring electrical equipment that is operative at a medium voltage that is isolated from a low voltage environment, the method comprising:
connecting a transmitter unit that is operative at the medium voltage to the equipment;
connecting an optical fiber to the transmitter unit and to a low voltage receiver that is operative at a low voltage within the low voltage environment; and
operating the transmitter unit to measure at least one measured property of the equipment and to produce an optical signal that is indicative of said at least one measured property.

17. The method of claim 16, wherein connecting the transmitter unit comprises directly connecting each component unit of a plurality of component units, each of the component units being configured to transmit an optical signal that is indicative of a property that is measured by that component unit, to a different bus bar of a system of bus bars, each of the bus bars carrying a different phase of a three phase electrical distribution system.

18. The method of claim 17, wherein connecting the transmitter unit further comprises connecting each of the component units via another of the component units to the bus bar to which that other component unit is connected.

19. The method of claim 16, further comprising operating the low voltage receiver to produce an output that is indicative of said at least one measured property.

20. A system for monitoring electrical equipment operative at a medium voltage that is isolated from a low voltage environment, the system comprising:
a transmitter unit operative at medium voltage to produce an optical signal that is indicative of at least one measured property of the electrical equipment;
an optical fiber that is connectable to the transmitter unit and that extends to the low voltage environment; and
a low voltage receiver that is connectable to the optical fiber in the low voltage environment, and that is operable to receive the optical signal via the optical fiber and to produce an output that is indicative of said at least one measured property.
